(19) United States
(12) Patent Application Publication
(10) Pub. No.: US 2003/0089938 A1
(43) Pub. Date: May 15, 2003

(54) Semiconductor device and method of manufacturing the same

(75) Inventors: Kaoru Saigoh, Kawasaki (JP); Nobutaka Ohyagi, Kawasaki (JP); Kouji Tani, Kawasaki (JP); Hisashi Miyazawa, Kawasaki (JP); Kazutaka Miura, Kawasaki (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU LIMITED, Kawasaki (JP)

(21) Appl. No.: 10/277,877

(22) Filed: Oct. 23, 2002

(30) Foreign Application Priority Data
Mar. 11, 2002 (JP) 2002-65270
Oct. 24, 2001 (JP) 2001-327022

(51) Int. Cl. H01L 27/108; H01L 29/76; H01L 31/119

(52) U.S. Cl. 257/296; 257/295; 257/310

(57) ABSTRACT

There is provided a semiconductor device which comprises capacitors having lower electrodes, which are formed of platinum on a first insulating film over a semiconductor substrate to have a contact region, and upper electrodes formed on the lower electrodes via a dielectric film respectively, a second insulating film formed on the capacitors, a hole formed in the second insulating film on the contact region of the lower electrode, and a wiring constructed by forming an underlying conductive film, a minimum thickness of which is thicker than 30 nm at a bottom of the hole, and an aluminum film sequentially, and formed from an inside of the hole to an upper surface of the second insulating film.

### CROSS-REFERENCE TO RELATED APPLICATIONS

This application is based upon and claims priority of Japanese Patent Applications No. 2002-65270, filed in Mar. 11, 2002, and No. 2001-327022, filed in Oct. 24, 2001, the contents being incorporated herein by reference.

### BACKGROUND OF THE INVENTION

1. Field of the Invention

The present invention relates to a semiconductor device and a method of manufacturing the same and, more particularly, a semiconductor device having a capacitor and a method of manufacturing the same.

2. Description of the Prior Art

The ferroelectric capacitor of the planar-type FeRAM (Ferroelectric Random Access Memory) has a structure shown in FIG. 1.

In FIG. 1, two MOS transistors each having the gate electrode 105a, 105b, which is formed on the semiconductor substrate 101 via the gate insulating film, and the impurity diffusion regions 106a, 106b, which are formed in the well region 103 on both sides of the gate electrode 105a, 105b respectively, are formed in the well region 103 surrounded by the element isolation insulating film 102 on the semiconductor substrate 101. These MOS transistors are covered with the first and second insulating films 104a, 104b.

The upper surface of the second insulating film 104b is planarized by the chemical mechanical polishing (CMP) method, and the ferroelectric capacitor Q₀ that is covered with the encapsulation layer 114 is formed on such upper surface. The ferroelectric capacitor Q₀ has the lower electrode 111a, the ferroelectric film 112a, and the upper electrode 111b. The lower electrode 111a is formed mainly of the platinum to control the crystal orientation of the ferroelectric film 112a.

In addition, the third insulating film 104c is formed on the encapsulation layer 114 and the second insulating film 104b.

Also, the silicide layer 107 is formed on the surfaces of the impurity diffusion regions 106a, 106b on both sides of two gate electrodes 105a, 105b respectively. The first contact hole 117a is formed on the silicide layer 107 in the region that is put between two gate electrodes 105a, 105b, while the second contact holes 117b are formed on the silicide layer 107 near both sides of the well region 103. Also, the third contact hole 117c is formed on the lower electrode 111a.

The first, second, and third conductive plugs 118a, 118b, 118c that are made of the glue layer and the tungsten layer respectively are formed in the first, second, and third contact holes 117a to 117c.

In addition, the fourth contact hole 115 is formed on the upper electrode 113a of the capacitor.

The conductive pad 120a is formed on the first conductive plug 118a and the third insulating film 104c around this plug.

Also, the first wirings 120b that are connected to the upper surfaces of the second conductive plugs 118b and are connected to the upper electrode 113a of the capacitor Q₀ via the fourth contact hole 115 are formed on the third insulating film 104c, and in addition the second wiring 120c is formed on the third conductive plug 118c formed on the lower electrode 111a.

The conductive pad 120a, the first wirings 120b, and the second wiring 120c is constructed by the laminated film consisting of the titanium nitride film and the aluminum film respectively.

By the way, in order to bury the tungsten in the first to third contact holes 117a to 117c deeply, the first, second, and third conductive plugs 118a, 118b, 118c made of the tungsten must be formed by the CVD method using tungsten hexafluoride (WF₆), silane (SiH₄), and hydrogen (H₂) as the reaction gas.

However, such reaction gas has the reducing property. As a result, if the reaction gas is supplied to the lower electrode 111a of the capacitor Q₀ through the contact hole 117c and then moved along the lower electrode 111a, such reaction gas reduces the ferroelectric film 112a made of the oxide to cause the degradation of the capacitor characteristics.

### SUMMARY OF THE INVENTION

It is an object of the present invention to provide a semiconductor device having a structure in which a peripheral region is not deteriorated by a conductive film formed in a contact hole on an electrode, and a method of manufacturing the same.

The above subject can be overcome by providing a semiconductor device which comprises transistor having a first impurity region and a second impurity region formed in a semiconductor substrate and gate electrodes formed over the semiconductor substrate; a first insulating film for covering the transistor; a capacitor, formed over the first insulating film, having a dielectric film made of one of ferroelectric material and high-dielectric material and an upper electrode and a lower electrode; a second insulating film, having a planarized surface, formed over the capacitor and the first insulating film; a first hole formed in the second insulating film over the first impurity region; a first plug formed in the first hole; a second hole formed in the second insulating film on the lower electrode of the capacitors; a third hole formed in the second insulating layer and on the upper electrode of the capacitor; a first conductive pattern made of a conductive film formed on the second insulating film, and connected to the upper electrode via the third hole and connected to the first plug; and a second conductive pattern made of the conductive film on the second insulating film, and connected to the lower electrode via the second hole.

Also, the above subject can be overcome by providing a semiconductor device which comprises an electrode, having a contact region, formed of platinum over a first insulating film over a semiconductor substrate; a second insulating film formed on the electrode; a hole formed in the second insulating film on the contact region of the electrode; and a buried conductive layer constructed by forming an underlying conductive film, a minimum thickness of which is thicker than 30 nm at a bottom of the hole, and an aluminum film sequentially, and formed from an inside of the hole to an upper surface of the second insulating film.

According to the present invention, in the structure in which the wiring formed on the insulating film for covering the capacitor is connected electrically to the lower electrode of the capacitor via the hole, such wiring is connected directly to the lower electrode without the intervention of the conductive plug. If the aluminum is employed as the wiring material, such aluminum film is formed by the sputter not to use the reducing gas. Therefore, the situation that the reducing gas is supplied to the dielectric film along the lower electrode is eliminated, and thus the deterioration of the capacitor characteristics caused in forming the lower electrode contact structure is prevented.

Also, according to the present invention, the underlying conductive film and the aluminum film are formed sequentially as the buried conductive film being formed in the hole on the electrode, and also the minimum thickness of the underlying conductive film on the bottom surface of the hole is formed thicker than 30 nm.

Therefore, since the aluminum can be filled in the hole on the electrode by the sputter, the surroundings of the electrode are never deteriorated by the reducing gas. In addition, since the minimum thickness of the conductive film, which serves as the underlying film of the aluminum formed in the hole, is set to more than 30 nm on the bottom surface of the hole, the reaction between the platinum film constituting the electrode and the aluminum film constituting the buried conductive layer is prevented sufficiently.

### BRIEF DESCRIPTION OF THE DRAWINGS

FIG. 1 is a sectional view showing the shape of the capacitor in the FeRAM in the prior art;

FIGS. 2A to 2N are sectional views showing steps of manufacturing a semiconductor device according to an embodiment of the present invention;

FIGS. 3A to 3J are sectional views, which are viewed from a I-I line in FIG. 2B, showing steps of manufacturing the semiconductor device according to the embodiment of the present invention;

FIG. 4 is a sectional view showing a connection state between a wiring and a capacitor lower electrode in a contact hole shown in FIG. 3J;

FIG. 5 is a sectional view showing a connection state between a wiring and a capacitor lower electrode in a contact hole in a reference semiconductor device;

FIG. 6 is a graph showing a relationship between a film thickness of a titanium nitride film and an aluminum/platinum reaction break temperature, in a structure in which a platinum film, a titanium nitride film, and an aluminum film are formed sequentially; and

FIG. 7 is a sectional view showing another example of the shape of the contact hole in the embodiment of the present invention.

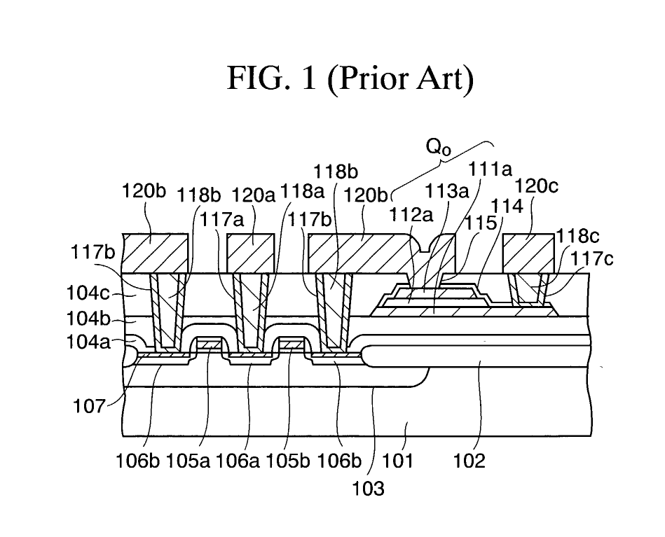

### DESCRIPTION OF THE PREFERRED EMBODIMENTS

Embodiments of the present invention will be explained with reference to the accompanying drawings hereinafter.

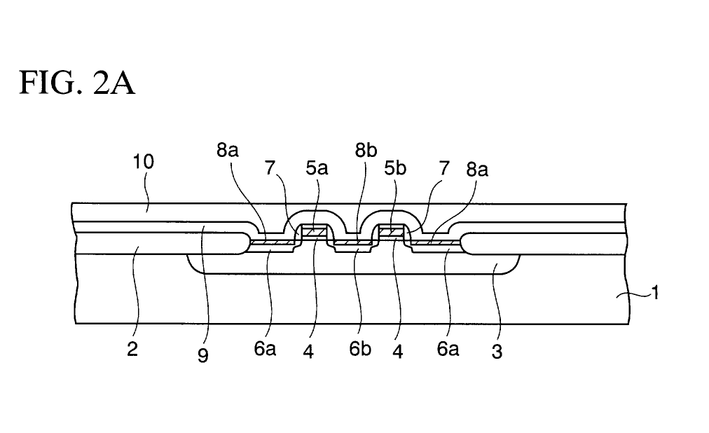

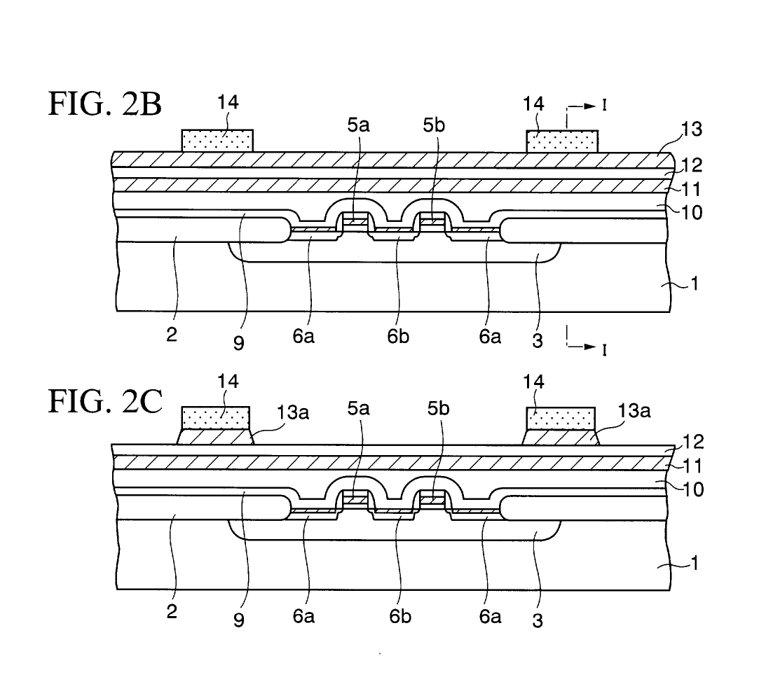

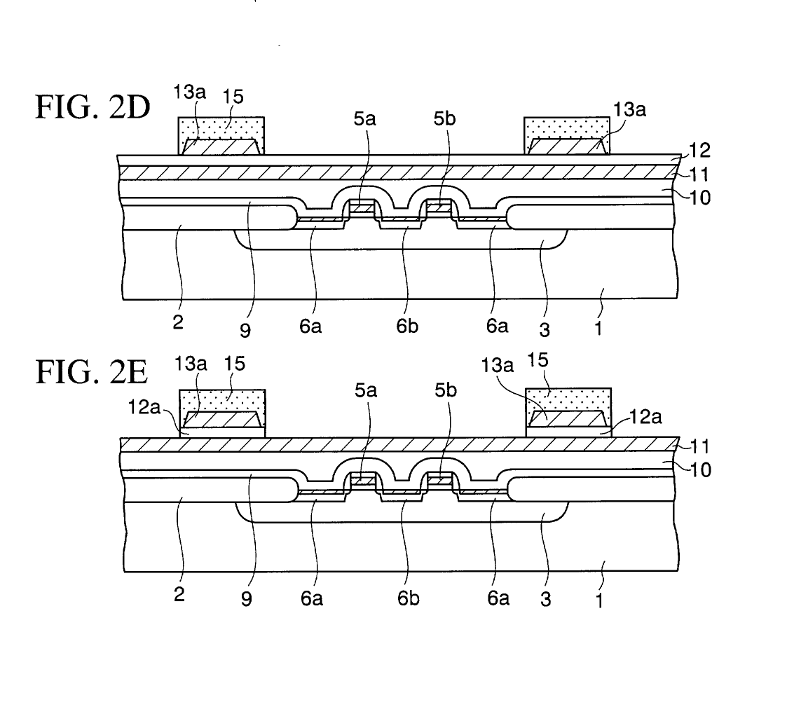

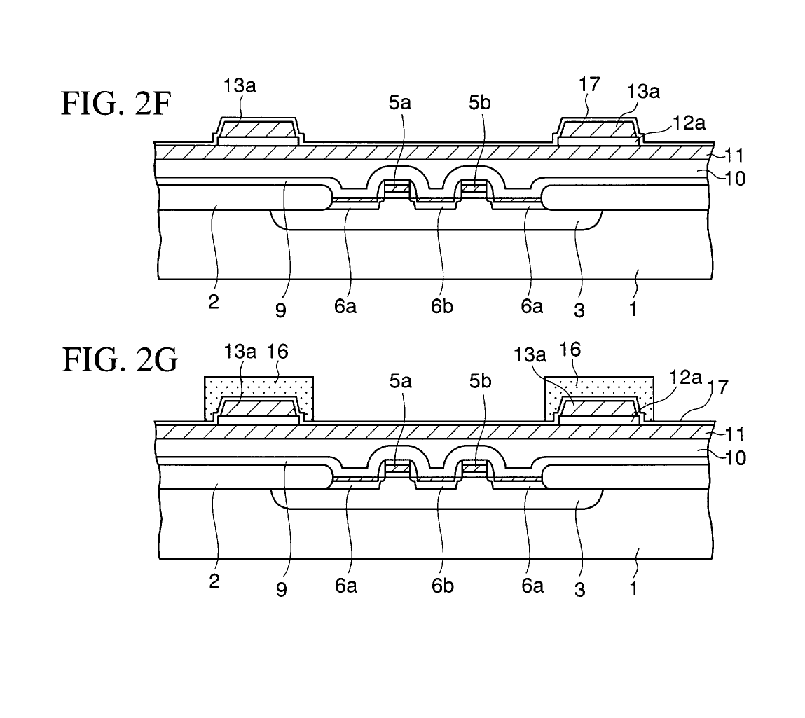

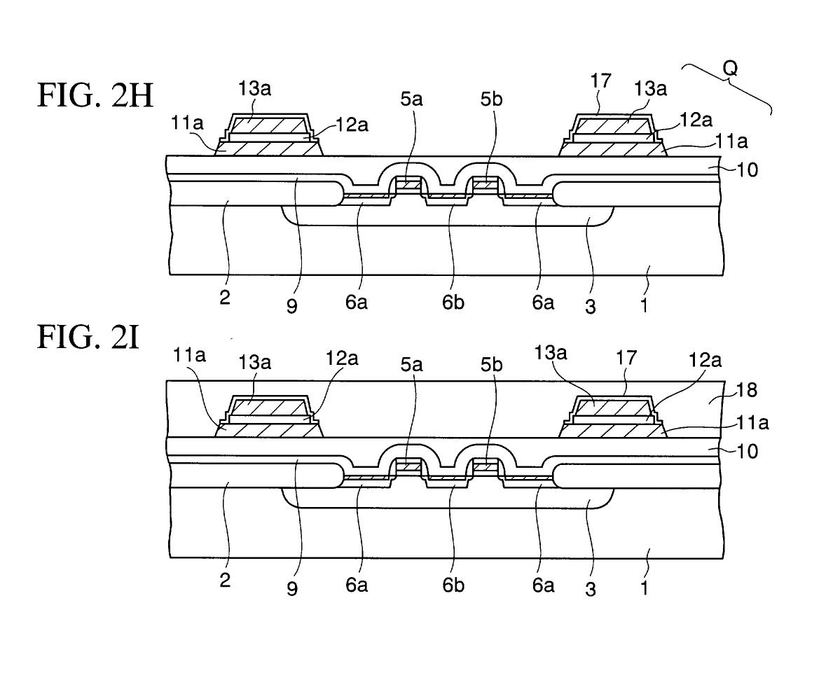

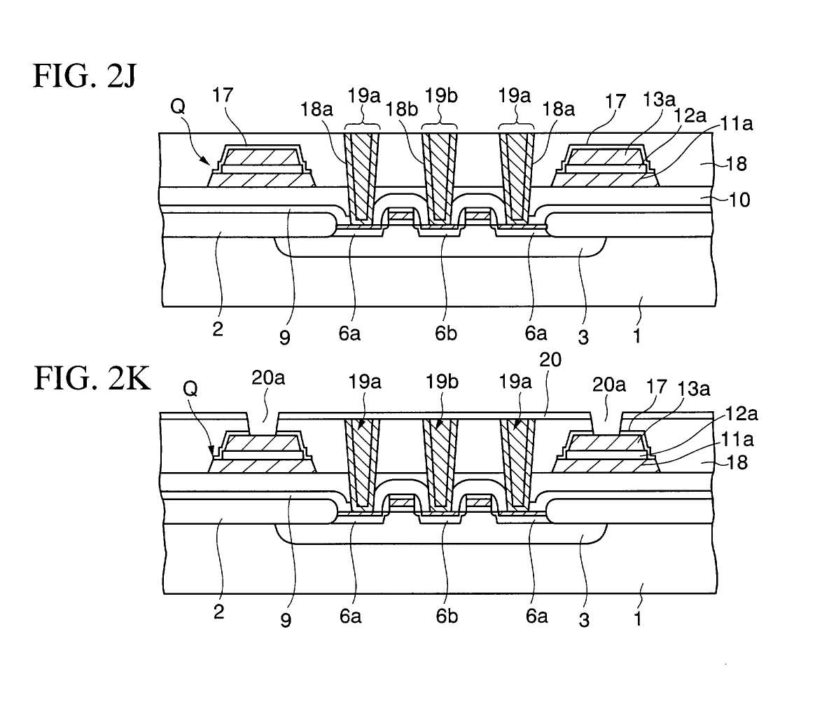

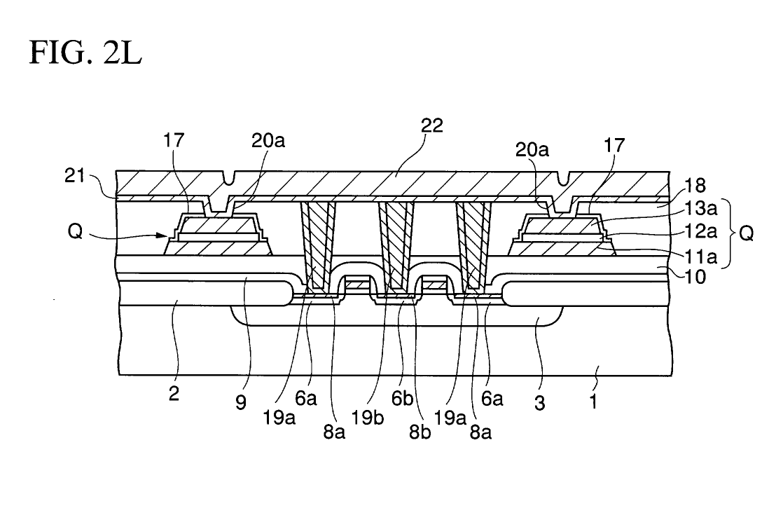

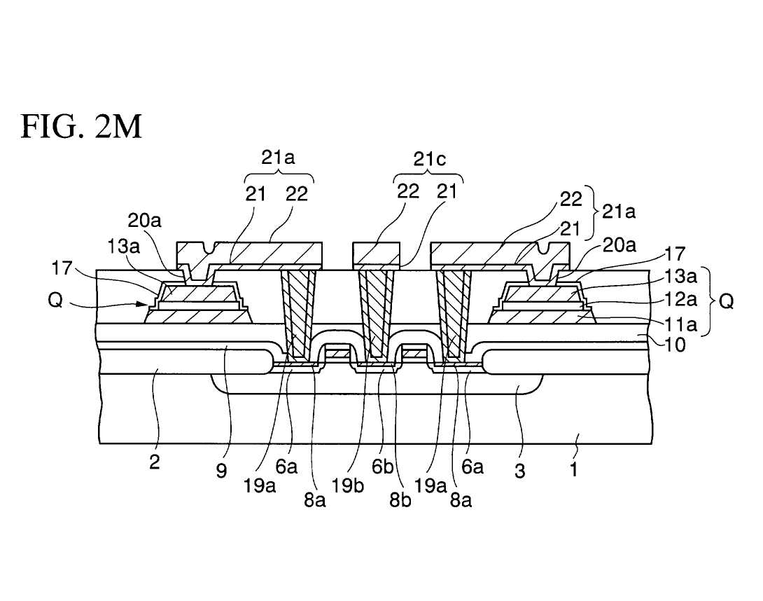

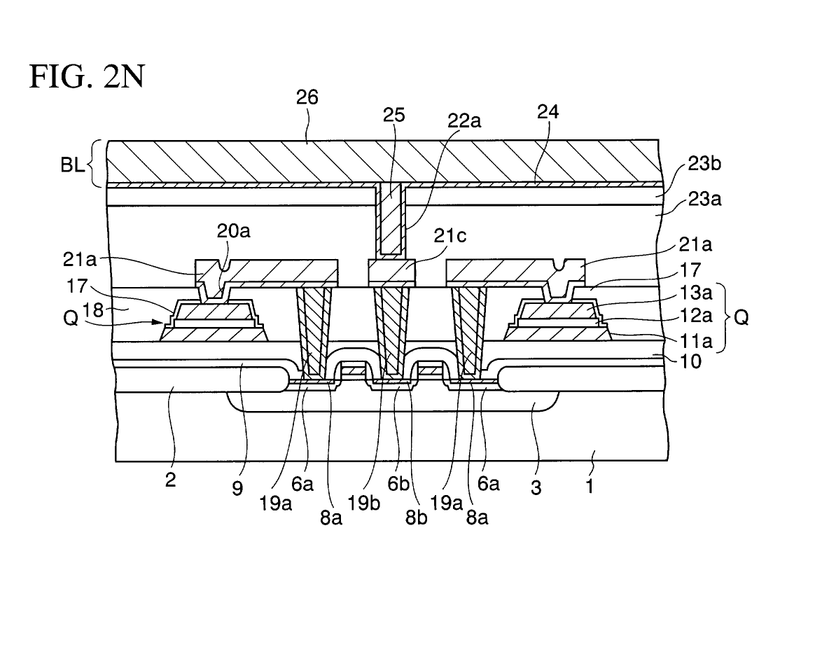

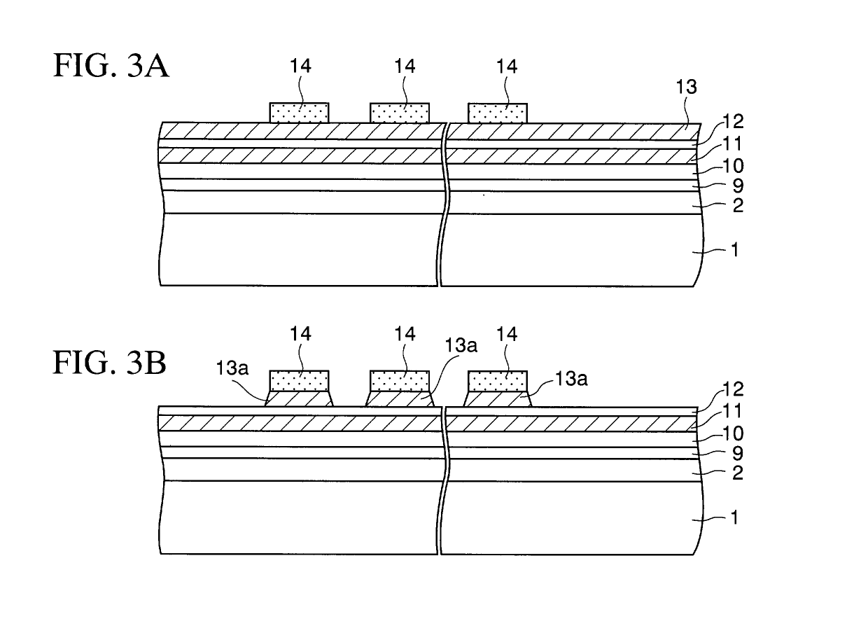

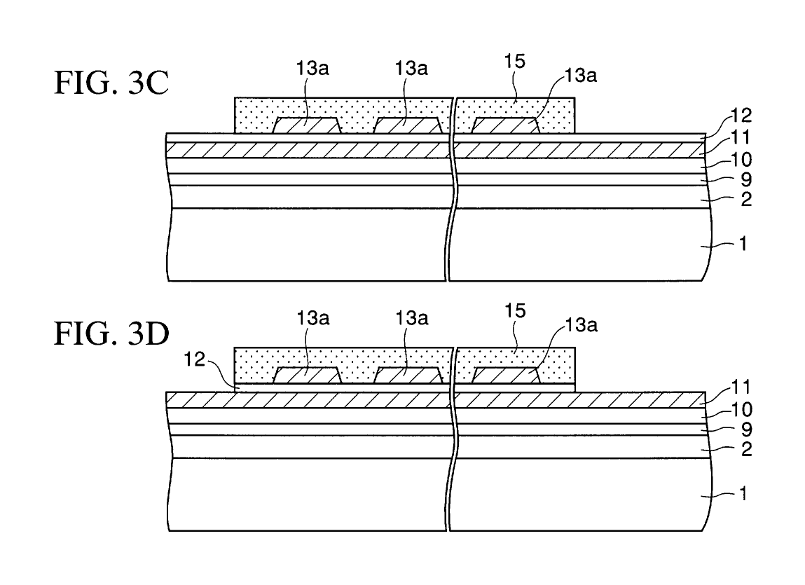

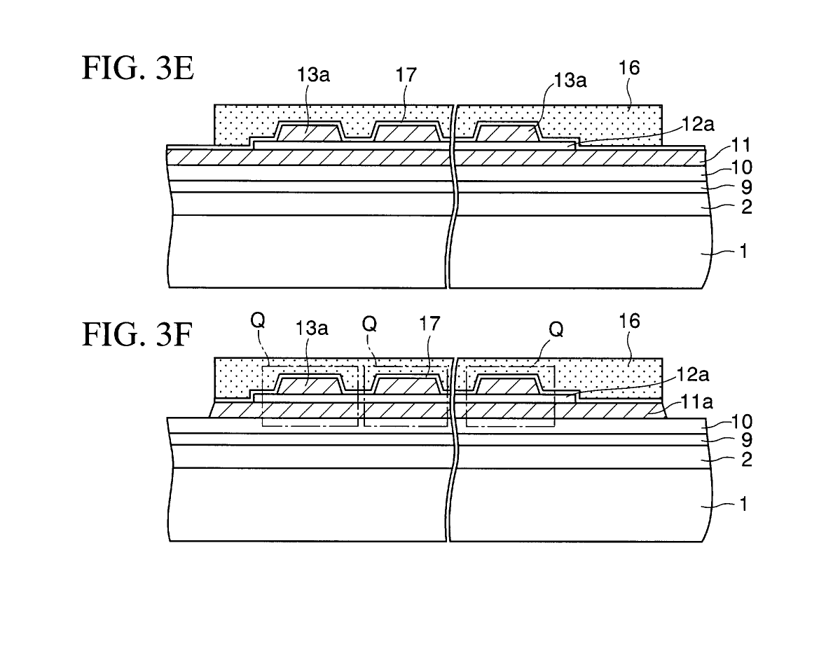

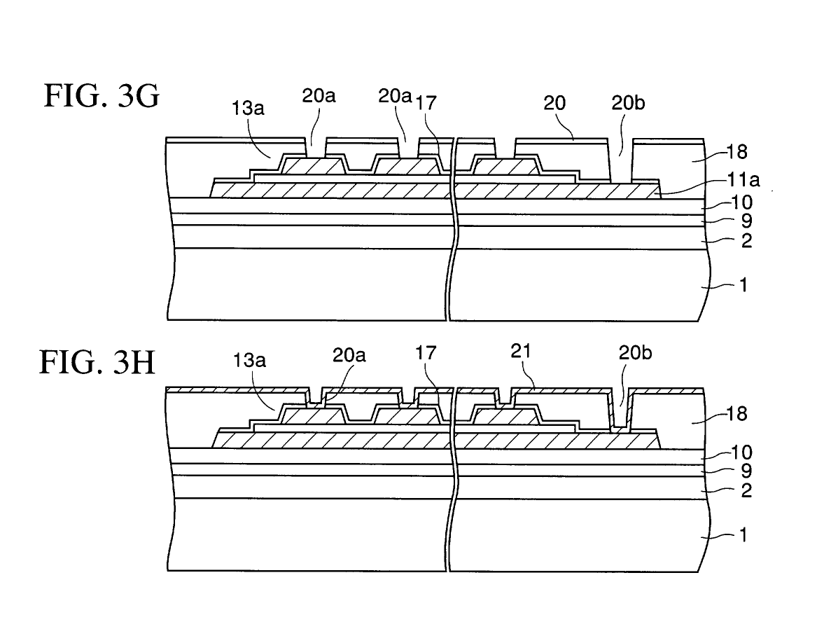

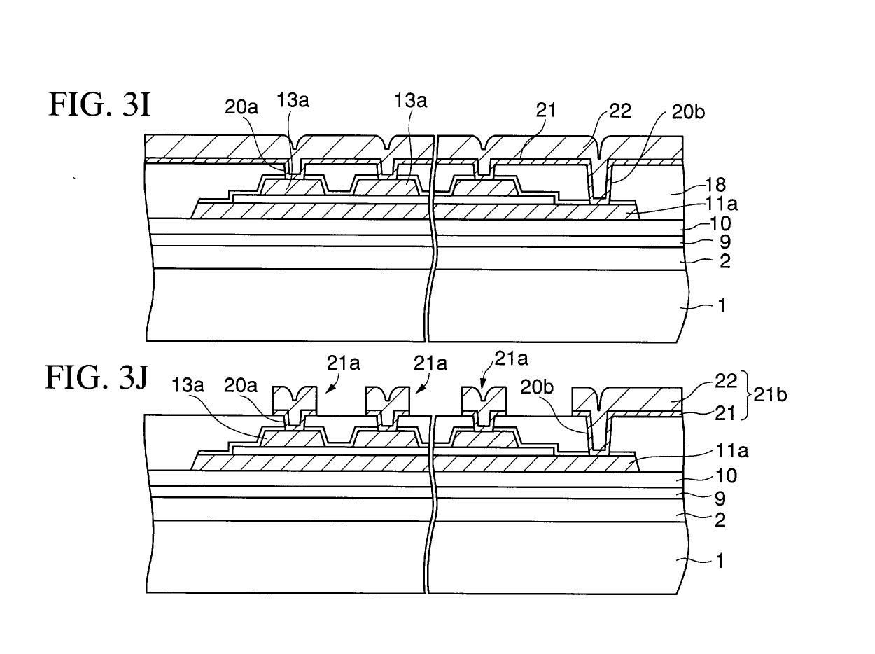

FIGS. 2A to 2N are sectional views showing steps of manufacturing a semiconductor device according to a first embodiment of the present invention. Also, FIGS. 3A to 3J are sectional views showing the formation of the capacitor and the formation of the wiring along the word line direction, in the semiconductor device according to the first embodiment of the present invention.

First, steps required to form a sectional structure shown in FIG. 2A will be explained hereunder.

An element isolation insulating film 2 is formed on a surface of an n-type or p-type silicon (semiconductor) substrate 1 by the LOCOS (Local Oxidation of Silicon) method. STI (Shallow Trench Isolation) may be employed as the element isolation insulating film 2.

After such element isolation insulating film 2 is formed, a p-type well 3 is formed in a predetermined active region (transistor forming region) in the memory cell region of the silicon substrate 1.

Then, a silicon oxide film is formed by thermally oxidizing a surface of the active region of the silicon substrate 1, and then used as a gate insulating film 4.

Then, a conductive film made of polysilicon or refractory metal silicide is formed on an overall upper surface of the silicon substrate 1. Then, gate electrodes 5a, 5b are formed on the gate insulating film 4 by patterning the conductive film into a predetermined shape by means of the photolithography method. Two gate electrodes 5a, 5b are arranged in almost parallel on one p-type well 3 in the memory cell region. These gate electrodes 5a, 5b constitute a part of the word line.

Then, n-type impurity diffusion regions 6a, 6b serving as source/drain of an n-channel MOS transistor are formed by ion-implanting the n-type impurity in the p-type well 3 on both sides of the gate electrodes 5a, 5b. Then, an insulating film is formed on an overall surface of the silicon substrate 1, and then the insulating film is etched back and left on both side portions of the gate electrodes 5a, 5b as sidewall insulating film 7. The insulating film is a silicon oxide (SiO₂) film formed by the CVD method, for example.

In addition, the n-type impurity diffusion regions 6a, 6b are formed into the LDD structure by implanting the n-type impurity ion into the p-type well 3 again while using the gate electrodes 5a, 5b and the sidewall insulating film 7 as a mask. In this case, in one p-type well 3, the n-type impurity diffusion region 6b being put between two gate electrodes 5a, 5b is connected electrically to the bit line described later, while two n-type impurity diffusion regions 6a being formed on both sides of the p-type well 3 are connected electrically to a capacitor upper electrode described later.

As descried above, two n-type MOSFETs are constructed by the gate electrodes 5a, 5b, the n-type impurity diffusion regions 6a, 6b, etc. in the p-type well 3 in the memory cell region.

Then, a refractory metal film is formed on the overall surface, and then refractory metal silicide layers 8a, 8b are formed on surfaces of the n-type impurity diffusion regions 6a, 6b respectively by heating this refractory metal film. Then, the unreacted refractory metal film is removed by the wet etching.

In addition, a silicon oxide nitride (SiON) film is formed on the overall surface of the silicon substrate 1 as a cover film 9, which covers the MOS transistors, by the plasma CVD method to have a thickness of about 200 nm. Then, a silicon dioxide (SiO₂) film of about 1.0 μm thickness is grown on the cover film 9 as a first interlayer insulating film 10 by the plasma CVD method using the TEOS gas. Then, the first interlayer insulating film 10 is polished by the chemical mechanical polishing (CMP) method to planarize its upper surface.

Next, steps required until a structure shown in FIG. 2B is formed will be explained hereunder.

First, a platinum (Pt) film of 100 to 300 nm thickness is formed on the first interlayer insulating film 10 by the DC sputter method, and this platinum film is used as a first conductive film 11. In order to improve the adhesiveness between the platinum film and the first interlayer insulating film 10, a titanium film of 10 to 30 nm thickness may be formed between them. In this case, the platinum film constituting the first conductive film 11 may be replaced with a platinum alloy film.

Then, PZT(Pb(Zr₁₋ₓTiₓ)O₃) is formed on the first conductive film 11 by the sputtering method to have a thickness of 100 to 300 nm, and this film is used as a ferroelectric film 12.

Then, the crystallizing process of the PZT film is carried out by putting the silicon substrate 1 into the oxygen atmosphere and then applying the RTA (Rapid Thermal Annealing) process to the PZT film constituting the ferroelectric film 12 at 725° C. for 20 seconds at the temperature rise rate of 125° C./sec.

As the method of forming the ferroelectric film 12, in addition to the above sputter method, there are the spin-on method, the sol-gel method, the MOD (Metal Organic Deposition) method, and the MOCVD method. Also, as the material of the ferroelectric film 12, the bismuth oxide compound such as PLZT (Lead Lanthanum Zirconate Titanate; (Pb_{1-3x/2}Laₓ) (Zr_{1-y}Ti_{y})O₃), SrBi₂(TaₓNb₁₋ₓ)₂O₉ (where 0<x≦1), Bi₄Ti₂O₁₂, etc. may be formed.

After such ferroelectric film 12 is formed, an iridium oxide (IrOₓ) film of 150 to 250 nm thickness is formed on this film as a second conductive film 13 by the sputtering method. In this case, as the second conductive film 13, a platinum film or a strontium ruthenate (SRO) film may be formed by the sputter method.

Then, the resist is coated on the second conductive film 13, and then resist patterns 14 each having an upper electrode shape are formed by exposing/developing this resist. A sectional view taken along a I-I line in FIG. 2B is shown in FIG. 3A.

Then, as shown in FIG. 2C and FIG. 3B, the second conductive film 13 is etched by using the resist patterns 14 as a mask, and thus the remaining second conductive film 13 is used as a capacitor upper electrode 13a.

Then, the resist patterns 14 are removed and then the ferroelectric film 12 is annealed in the oxygen atmosphere at the temperature of 650° C. for 60 minutes via the capacitor upper electrodes 13a. This annealing is carried out to recover the ferroelectric film 12 from the damage incurred during the sputtering or the etching.

Then, as shown in FIG. 2D and FIG. 3C, second resist patterns 15 are formed by coating the resist on the capacitor upper electrodes 13a and the ferroelectric film 12 and then exposing/developing this resist. The second resist patterns 15 have stripe shapes that passes on a plurality of capacitor upper electrodes 13a arranged in the extending direction of the gate electrodes (word lines) 5a, 5b.

Then, as shown in FIG. 2E and FIG. 3D, the ferroelectric film 12 is etched by using the second resist patterns 15 as a mask, and thus the patterned ferroelectric film 12 is used as a capacitor dielectric film 12a.

Then, the second resist patterns 15 are removed and then the capacitor dielectric films 12a are annealed in the oxygen atmosphere at the temperature of 650° C. for 60 minutes.

Then, as shown in FIG. 2F, an Al₂O₃ film of 50 nm thickness is formed on the capacitor upper electrodes 13a, the capacitor dielectric film 12a, and the first conductive film 11 as an encapsulation layer 17 by the sputtering method at the ordinary temperature. This encapsulation layer 17 is formed to protect the capacitor dielectric films 12a, which are ready to reduce, from the hydrogen. As the encapsulation layer 17, a PZT film, a PLZT film, or a titanium oxide film may be formed.

Then, the film quality of the capacitor dielectric film 12a under the encapsulation layer 17 is improved by applying the RTA process to the film 12a in the oxygen atmosphere at 700° C. for 60 seconds at the temperature rise rate of 125° C./sec.

Then, as shown in FIG. 2G and FIG. 3E, third resist patterns 16 each having a stripe shape that longer than the capacitor dielectric film 12a in the extending direction of the word line are formed on and along the capacitor dielectric films 12a by coating the resist on the encapsulation layer 17 and then exposing/developing this resist.

Then, as shown in FIG. 3F, the encapsulation layer 17 and the first conductive film 11 are etched by using the third resist patterns 16 as a mask, and thus the stripe-like first conductive film 11 being left under the third resist pattern 16 is used as a capacitor lower electrode 11a. The capacitor lower electrode 11a has a shape that protrudes from the capacitor dielectric film 12a and is called a plate line. Then, the third resist patterns 16 are removed.

Accordingly, as shown in FIG. 2H, one ferroelectric capacitor Q is constructed by one stripe-like capacitor upper electrode 13a, the underlying capacitor dielectric film 12a, and the capacitor lower electrode 11a.

Then, the capacitor dielectric films 12a is annealed in the oxygen atmosphere at the temperature of 650° C. for 60 minutes to recover from the damage.

Then, as shown in FIG. 2I, an SiO₂ film of 1200 nm thickness is formed on the ferroelectric capacitor Q and the first interlayer insulating film 10 as a second interlayer insulating film 18 by the CVD method. Then, a surface of the second interlayer insulating film 18 is planarized by the CMP method. The growth of the second interlayer insulating film 18 may be executed by using either silane (SiH₄) or TEOS as the reaction gas. The planarization of the surface of the second interlayer insulating film 18 is executed up to a thickness of 200 nm from an upper surface of the capacitor upper electrode 13a.

Next, steps required until a structure shown in FIG. 2J is formed will be explained hereunder.

First, contact holes 18a, 18b are formed on the n-type impurity diffusion layers 6a, 6b by patterning the first and second interlayer insulating films 10, 18 and the cover film 9. As the etching gas for the first and second interlayer insulating films 10, 18 and the cover film 9, the CF gas, e.g., the mixed gas obtained by adding Ar to CF₄, is employed.

Then, a titanium (Ti) film of 20 nm thickness and a titanium nitride (TiN) film of 50 nm thickness are formed on an upper surface of the second interlayer insulating film 18 and on inner surfaces of the contact holes 18a, 18b by the sputtering method respectively, and these films are used as a glue layer. In addition, a tungsten film is formed on the glue layer by the CVD method using the mixed gas consisting of tungsten fluoride gas (WF₆), argon, and hydrogen to bury the contact holes 18a, 18b completely.

In addition, the tungsten film and the glue layer on the second interlayer insulating film 18 are removed by the CMP method, but they are left only in the contact holes 18a, 18b. Accordingly, the tungsten film and the glue layer being left in the contact holes 18a, 18b are used as first and second conductive plugs 19a, 19b.

In one p-type well 3 in the memory cell region, the first conductive plug 19b formed on the center n-type impurity diffusion region 6b being put between two gate electrodes 5a, 5b is connected electrically to the bit line described later, while two second conductive plugs 19a formed near both sides of the p-type well 3 are connected electrically to the capacitor upper electrode 13a via the wiring described later.

Then, the second interlayer insulating film 18 is annealed at the temperature of 390° C. in the vacuum chamber to discharge the moisture to the outside.

Next, steps required until a structure shown in FIG. 2K and FIG. 3G is formed will be explained hereunder.

First, a SiON film is formed on the second interlayer insulating film 18 and the conductive plugs 19a, 19b by the plasma CVD method as an oxidation preventing film 20 to have a thickness of 100 nm, for example. This SiON film is formed by using the mixed gas of silane (SiH₄) and N₂O.

Then, the photoresist (not shown) is coated on the oxidation preventing film 20, and then windows are formed on the capacitor upper electrodes 13a and extended portions of the capacitor lower electrodes 11a by exposing/developing this photoresist. Then, contact holes 20a, 20b are formed on the capacitor upper electrodes 13a and the capacitor lower electrode 11a respectively by etching the encapsulation layer 17, the second interlayer insulating film 18, and the oxidation preventing film 20 while using the photoresist as a mask.

In this case, an opening size of the contact hole 20b on the capacitor lower electrode 11a is set to 1.8 μm×1.8 μm or 0.6 μm×1.8 μm, for example, at its upper portion. It is preferable that the opening portion should be designed to have one side of more than 0.6 μm.

Then, the photoresist (not shown) is removed. Then, the film quality of the capacitor dielectric film 12a is improved by annealing the capacitor dielectric film 12a in the oxygen atmosphere at 550° C. for 60 minutes. In this case, the oxidation of the conductive plugs 19a, 19b can be prevented by the oxidation preventing film 20.

Next, steps required to form a structure shown in FIG. 3H will be explained hereunder.

First, the oxidation preventing film 20 is removed by applying the dry etching using the CF gas.

Then, a titanium nitride (TiN) film is formed on the second interlayer insulating film 18, the conductive plugs 19a, 19b, and inner surfaces of the contact holes 20a as an underlying conductive film 21 by the sputter. This underlying conductive film 21 functions as a barrier film that has a good adhesiveness to the aluminum film described later. The constituting material of the underlying conductive film 21 is not limited to titanium nitride, and either a laminated structure of titanium nitride and titanium or tungsten nitride may be employed.

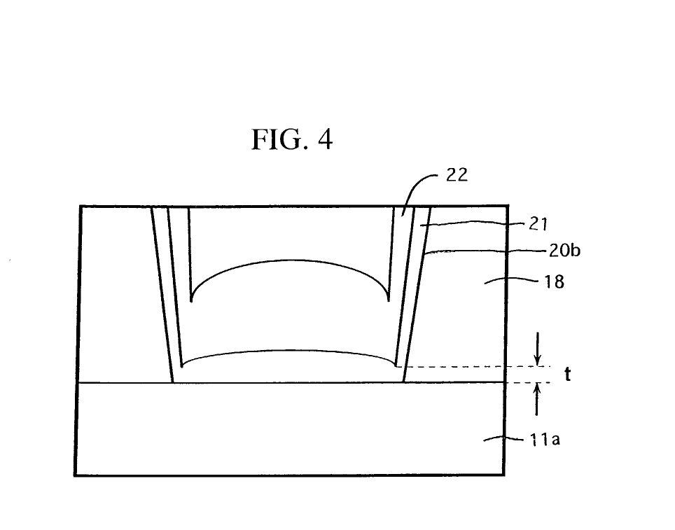

The TiN film 21 in contact hole 20b on the capacitor lower electrode 11a is formed such that, as shown in FIG. 4, a film thickness of the thinnest portion on the bottom surface, e.g., a film thickness t of the peripheral portion of the bottom of the contact hole 20b, can be set to more than 35 nm. In the case that the opening size of the contact hole 20b on the capacitor lower electrode 11a is set to 1.8 μm×1.8 μm or 0.6 μm×1.8 μm, the film thickness of the TiN film 21 at the thin portion on the bottom portion in the contact hole 20b is more than 60 nm if a thickness of the TiN film on the second interlayer insulating film 18 is formed in excess of 150 nm.

Then, as shown in FIG. 2L and FIG. 3I, an aluminum film 22 is formed on the underlying conductive film 21 by the sputter. The aluminum film 22 is formed in about 500 nm thick on the second interlayer insulating film 18. In this case, sometimes the copper is contained in the aluminum film 22.

Then, as shown in FIG. 2M and FIG. 3J, a lower electrode leading wiring 21b that is extended from the inside of the contact hole 20b on the capacitor lower electrode 11a to the outside is formed by patterning the aluminum film 22 and the underlying conductive film 21 by virtue of the photolithography method. At the same time, a via contact pad 21c, which is formed on the conductive plug 19b in the middle of the p-type well 3, and upper electrode leading wirings 21a, which are connected from upper surfaces of the conductive plugs 19a on both sides of the p-type well 3 to upper surfaces of the capacitor upper electrodes 13a via the contact holes 20a, are formed by patterning the aluminum film 22 and the underlying conductive film 21.

Accordingly, the capacitor lower electrode 11a is connected to the peripheral circuit region (not shown) via the lower electrode leading wiring 21b. Also, the capacitor upper electrodes 13a are connected to the n-type impurity diffusion regions 6a, which are formed near both sides of the p-type well 3, via the upper electrode leading wirings 21a, the conductive plugs 19a, and the refractory metal silicide layers 8a.

In this case, the long through sputtering may be employed as the sputter to form the underlying conductive film 21 and the aluminum film 22.

Next, steps required to form a structure shown in FIG. 2N will be explained hereunder.

First, an SiO₂ film of 2300 nm thickness is formed as a third interlayer insulating film 23a by the plasma CVD method using TEOS as a source. Accordingly, the second interlayer insulating film 18, the upper electrode leading wirings 21a, the lower electrode leading wiring 21b, and the contact pad 21c are covered with the third interlayer insulating film 23a. Subsequently, a surface of the third interlayer insulating film 23a is planarized by the CMP method.

Then, a protection insulating film 23b made of SiO₂ is formed on the third interlayer insulating film 23a by the plasma CVD method using TEOS. Then, a hole 22a is formed on the contact pad 21c, which is formed in the middle of the p-type well 3 in the memory cell region, by patterning the third interlayer insulating film 23a and the protection insulating film 23b.

Then, a glue layer 24 made of titanium nitride (TiN) having a thickness of 90 nm to 150 nm, is formed by the sputter method on an upper surface of the protection insulating film 23b and an inner surface of the hole 22a. Then, the substrate temperature is set to about 400° C., and then a bracket tungsten film 25 is formed by the CVD method using WF₆ to bury the hole 22a.

Then, the bracket tungsten film 25 is etched back to leave only in the hole 22a, and thus the bracket tungsten film 25 in the hole 22a is used as a second-layer conductive plug.

Then, a metal film 26 is formed on the glue layer 24 and the bracket tungsten film 25 by the sputter method. Then, a bit line BL, which is connected electrically to the n-type impurity diffusion region 6b via the second-layer conductive plug 25, the contact pad 21c, the first-layer conductive plug 19b, and the refractory metal silicide layer 8b, is formed by patterning the metal film 26 by means of the photolithography method.

In the above embodiment, when the film thickness of the TiN film serving as the underlying conductive film 21, which is formed in the contact hole 20b on the capacitor lower electrode 11a, is set to exceed 35 nm at the thinnest portion of the bottom portion of the contact hole 20b, the reaction of the aluminum film 22, which is formed on the underlying conductive film 21 in the contact hole 20b, with the capacitor lower electrode 11a made of platinum can be prevented.

In this case, if the capacitor upper electrodes 13a are formed of platinum, the reaction of the aluminum film 22 formed on the underlying conductive film 21 in the contact holes 20a with the capacitor upper electrodes 13a under the lower conductive film 21 can be prevented.

In this manner, the fact that the reaction between the capacitor lower electrode 11a and the aluminum film 22 can be prevented by setting the thickness of the TiN film 21 to more than 35 nm can be validated by the experiment shown in Table 1.

TABLE 1

| | LTS-TiN | | | | | | | | | |
|---|---|---|---|---|---|---|---|---|---|---|
| | Thickness | Break Anneal (° C. 30 min: N₂) | | | | | | | | |
| Base | (nm) | 380 | 390 | 400 | 410 | 420 | 430 | 440 | 450 | 460 |
| Pt | 35 | OK | OK | OK | OK | OK | Break | — | — | — |
| H-Pt | 35 | OK | Break | — | — | — | — | — | — | — |
| | 60 | OK | OK | OK | OK | OK | Break | — | — | — |
| | 80 | OK | OK | OK | OK | OK | OK | Break | — | — |

As the sample employed in the experiment shown in Table 1, the first sample obtained by forming the platinum film, the titanium nitride film having the thickness of 35 nm, and the aluminum film sequentially on the substrate was prepared. The platinum film in this case was formed in the substrate temperature range from the room temperature to about 100° C. by the sputter. This platinum film is given as “Pt” in Table 1.

Also, as another sample, the second sample obtained by forming the high-temperature platinum film, the titanium nitride film, and the aluminum film sequentially on the substrate was prepared. The high-temperature platinum film in the second sample was formed by the sputter while heating the substrate at 550° C. This platinum film being grown at the high temperature is given as “H—Pt” in Table 1. Also, three samples in which the thickness of the titanium nitride film is set to 35 nm, 60 nm, and 80 nm respectively were prepared as the second sample.

In the formation of respective samples, the surface of the aluminum film is etched slightly prior to the formation of the titanium nitride film. This is because, as shown in FIG. 3G, such surface of the aluminum film can deal with the event that the surface of the lower electrode 11a made of platinum is etched in forming the contact hole 20b.

When these samples were break-annealed separately for 30 minutes at various temperatures in the nitrogen atmosphere, results shown in Table 1 were derived.

According to Table 1, in the first sample, if the thickness of the titanium nitride film is set to 35 nm, the reaction between the low-temperature grown platinum film and the aluminum film in the heating at 420° C. could be prevented.

Also, in the second sample, if the thickness of the titanium nitride film is set to 35 nm, the reaction between the high-temperature grown platinum film and the aluminum film occurs at 390° C. However, in the second sample, it was found that, if the thickness of the titanium nitride film is set to at least 60 nm, the reaction between the high-temperature grown platinum film and the aluminum film in the heating at the temperature of 420° C. can be prevented.

According to this, if the low-temperature grown platinum film is formed on the interlayer insulating film 10 as the capacitor lower electrode 11a, the titanium nitride film 21 which is formed on the bottom of the contact hole 20b on the capacitor lower electrode 11a needs the thickness of more than 35 nm as the minimum film thickness.

Also, if the high-temperature grown platinum film is formed on the interlayer insulating film 10 as the capacitor lower electrode 11a, the titanium nitride film 21 which is formed at the bottom of the contact hole 20b on the capacitor lower electrode 11a needs the thickness of more than 60 nm.

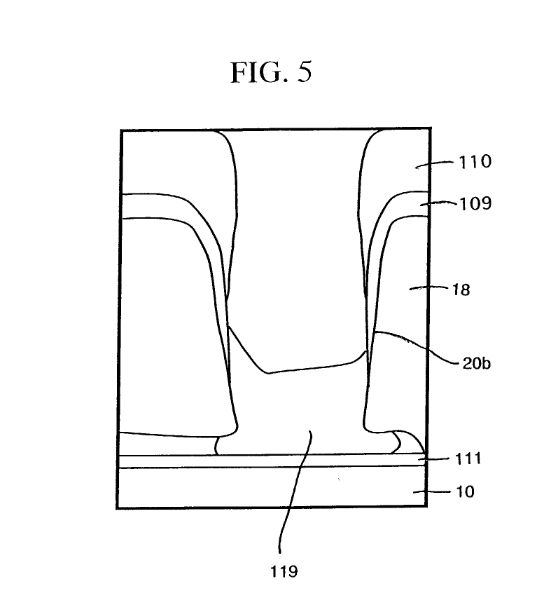

In contrast, as shown in FIG. 5, the titanium nitride film 109 formed in the contact hole 20b becomes thinner than 35 nm, a reaction layer 119 is produced by the reaction between the aluminum film 110 and the platinum lower electrode 111 to expand. Further, in some case the insulating film 18 is lifted up, and in the worst case the cracks appear in the insulating film 18.

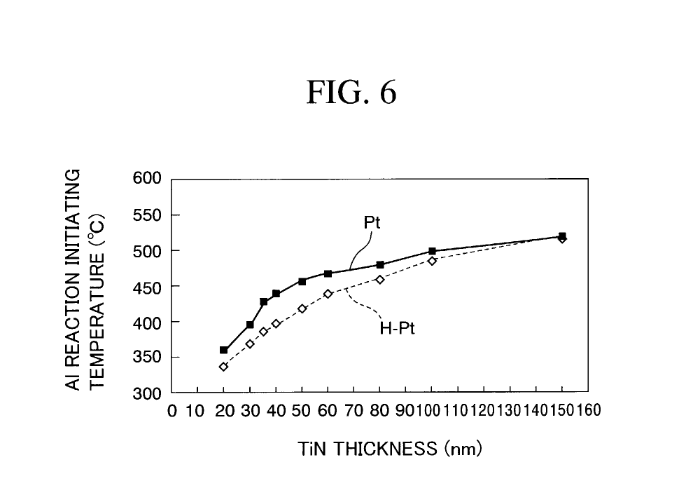

When the inventors of the present invention prepared plural sheets of sample, in which the titanium nitride film and the aluminum film are formed sequentially on the platinum film by the long through sputtering (LTS) method, and then examined a relationship between the thickness of the titanium nitride film and the aluminum film/platinum film break temperature, results shown in FIG. 6 are obtained. In this case, the platinum film formed by setting the substrate temperature to 550° C. is defined as the high-temperature platinum film, and the platinum film formed by setting the substrate temperature to 100° C. or less is defined as the low-temperature platinum film.

According to FIG. 6, in the sample in which the aluminum film is formed on the low-temperature grown platinum (Pt) film via the titanium nitride film, it was found that, when the thickness of the titanium nitride film is 30 nm, the reaction between the low-temperature grown platinum film and the aluminum film is initiated at the temperature of 400° C. In other words, in order to prevent the reaction between the low-temperature grown platinum film and the aluminum film at the temperature of 400° C., the titanium nitride film must be formed to have the thickness that is thicker than 30 nm. If the temperature is lower than 400° C., the thickness of the titanium nitride film may be set smaller than 30 nm correspondingly. As a result, in order to prevent the reaction between the low-temperature grown platinum film and the aluminum film at the temperature of less than 400° C., the thickness of the titanium nitride film may be set thicker than 30 nm.

Also, according to FIG. 6, in the sample in which the aluminum film is formed on the high-temperature grown platinum (H-Pt) film via the titanium nitride film, it was found that, when the thickness of the titanium nitride film is 40 nm, the reaction between the high-temperature grown platinum film and the aluminum film is initiated at the temperature of 400° C. In other words, in order to prevent the reaction between the high-temperature grown platinum film and the aluminum film at the temperature of 400° C., the titanium nitride film must be formed to have the thickness that is thicker than 40 nm. If the temperature is lower than 400° C., the thickness of the titanium nitride film may be set smaller than 40 nm correspondingly. As a result, in order to prevent the reaction between the high-temperature grown platinum film and the aluminum film at the temperature of less than 400° C., the thickness of the titanium nitride film may be set thicker than 40 nm.

In this case, the reason for selecting 400° C. as a reference temperature is that, in order to prevent the degradation of the lower electrode leading wiring 21b made of the aluminum film 22 after the lower electrode leading wiring 21b shown in FIG. 3J is formed, preferably the overlying films 23a, 23b, etc. should be formed at the temperature of 400° C. or less.

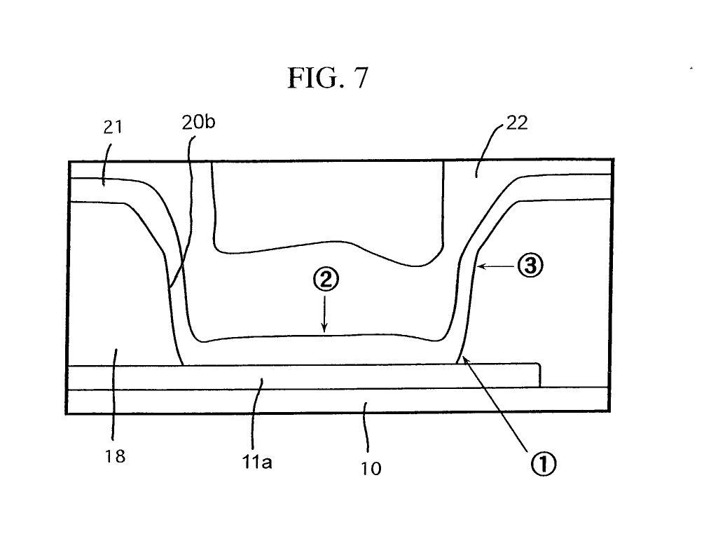

Meanwhile, as shown in FIG. 7, a shape of the contact hole 20b, which is formed in the second interlayer insulating film 18 on the capacitor lower electrode 11a, can be formed to expand its upper portion like a wine glass by changing the sputter etching conditions of the second interlayer insulating film 18. Then, the thickness of the titanium nitride film at the bottom portion of the contact hole 20b can be increased by expanding the upper portion of the contact hole 20b.

Then, as shown in FIG. 7, when an inclination of an upper inner surface of the contact hole 20b on the capacitor lower electrode 11a is set gentler than that of a lower inner surface to form the contact hole 20b wide and then the thickness of the titanium nitride film formed in the contact hole 20b was examined at \mathring{1} a periphery of the bottom surface of the contact hole, \mathring{2} a center of the bottom surface of the contact hole, and \mathring{3} an inner peripheral surface of the contact hole, results as shown in Table 2 are obtained. Thus, the thickness exceeds 35 nm at the thinnest portion.

In this case, an “upper” portion, a “middle” portion, a “lower” portion, a “left” portion, and a “right” portion of the wafer shown in Table 2 indicate respective positions on the wafer when the orient flat portion of the semiconductor wafer.

TABLE 2

| | | in-wafer | | | | |
|---|---|---|---|---|---|---|
| BEC size | location | upper | middle | lower | left | right |
| 0.6 × 1.8 μm | \mathring{1} | 45 nm | 52 nm | 37 nm | 52 nm | 50 nm |
| | \mathring{2} | 73 nm | 73 nm | 93 nm | 93 nm | 87 nm |
| | \mathring{3} | 52 nm | 43 nm | 45 nm | 39 nm | 35 nm |
| 1.8 μm□ | \mathring{1} | 73 nm | 95 nm | 89 nm | 62 nm | 62 nm |
| | \mathring{2} | 129 nm | 187 nm | 114 nm | 135 nm | 187 nm |
| | \mathring{3} | 41 nm | 54 nm | 43 nm | 41 nm | 52 nm |

In the above embodiment, in the structure in which the lower electrode leading wiring 21b formed on the second interlayer insulating film 18 for covering the capacitors Q is connected to the lower electrode 11a of the capacitor Q via the contact hole 19b, such lower electrode leading wiring 21b is connected directly to the lower electrode 11a without the intervention of the conductive plug.

Therefore, the contact holes 20a, 20b can be formed simultaneously on the upper electrode 13a and the lower electrode 11a of the capacitor Q respectively. As a result, it is possible to eliminate the necessity of forming the contact holes 18a, 18b, whose depth is largely different from that of the contact hole 20b, on the impurity diffusion regions 6a, 6b at the same time when the contact hole 20b is formed on the lower electrode 11a, and thus the condition setting of the contact holes 18a, 18b, 20a, 20b can be facilitated.

As described above, according to the present invention, the wiring that is formed from the hole, formed on the electrode, to the upper surface of the insulating film is formed as the multi-layered structure consisting of the underlying conductive film and the aluminum film, and also the minimum thickness of the underlying conductive film on the bottom surface of the hole is formed thicker than 30 nm. Therefore, the reaction between the platinum constituting the electrode and the aluminum constituting the wiring can be prevented sufficiently by the underlying conductive film.

In addition, since the aluminum can be easily filled in the hole by the PVD, the situation that the surroundings of the electrode is put in the reducing atmosphere via the electrode can be prevented. If such electrode is the lower electrode or the upper electrode of the capacitor, the deterioration of the ferroelectric film of the capacitor can be prevented.

What is claimed is:

1. A semiconductor device comprising:
a transistor having a first impurity region and a second impurity region formed in a semiconductor substrate and gate electrodes formed over the semiconductor substrate;
a first insulating film for covering the transistor;
a capacitor, formed over the first insulating film, having a dielectric film made of one of ferroelectric material and high-dielectric material and an upper electrode and a lower electrode;
a second insulating film, having a planarized surface, formed over the capacitor and the first insulating film;
a first hole formed in the second insulating film over the first impurity region;
a first plug formed in the first hole;
a second hole formed in the second insulating film on the lower electrode of the capacitor;
a third electrode formed in the second insulating film and on the upper electrode of the capacitor;
a first conductive pattern made of a conductive film formed on the second insulating film, and connected to the upper electrode via the third hole and connected to the first plug; and
a second conductive pattern made of the conductive film on the second insulating film, and connected to the lower electrode via the second hole.

2. A semiconductor device according to claim 1, wherein the first hole is extended in the first insulating film.

3. A semiconductor device according to claim 1, wherein a surface of the first insulating film is planarized.

4. A semiconductor device comprising:
an electrode, having a contact region, formed of platinum over a first insulating film over a semiconductor substrate;
a second insulating film formed over the electrode;
a hole formed in the second insulating film on the contact region of the electrode; and
a buried conductive layer constructed by forming an underlying conductive film, a minimum thickness of which is thicker than 30 nm at a bottom of the hole, and an aluminum film sequentially, and formed from an inside of the hole to an upper surface of the second insulating film.

5. A semiconductor device according to claim 4, further comprising: a capacitor having the electrode as a lower electrode, and a dielectric film formed on the electrode, and an upper electrode formed on the dielectric film.

6. A semiconductor device according to claim 4, wherein the underlying conductive film is formed of any one of titanium nitride, titanium nitride/titanium laminated layer, and tungsten nitride.

7. A semiconductor device according to claim 4, wherein a thickness of the underlying conductive film is in excess of 125 nm on the second insulating film.

8. A semiconductor device according to claim 4, wherein an upper portion of the hole is expanded rather than a lower portion.

9. A semiconductor device according to claim 4, wherein the upper portion of the hole is expanded like a wine glass.

10. A semiconductor device according to claim 4, wherein an aspect ratio of the hole is less than 2.

11. A semiconductor device according to claim 4, wherein the dielectric film is formed of ferroelectric material.

12. A semiconductor device according to claim 4, wherein the lower electrodes are formed of a high-temperature platinum film formed in heating, and a minimum thickness of the underlying conductive film is thicker than 40 nm at the bottom of the hole.

13. A semiconductor device according to claim 4, wherein other elements are contained in the aluminum film formed over the second insulating film.

14. A manufacturing method of a semiconductor device comprising the steps of:
forming a first insulating film over a semiconductor substrate;
forming a capacitor having lower electrode, having a contact region, formed of platinum formed over the first insulating film, and a dielectric film formed on the lower electrode, and an upper electrode formed on the dielectric film;
forming a second insulating film over the capacitor;
forming a hole over the contact region of the lower electrode and in the second insulating film;
forming an underlying conductive film, a minimum thickness of which is thicker than 30 nm at bottom of the hole, in the hole and on an upper surface of the second insulating film;
forming an aluminum film on the underlying conductive film; and
forming a wiring, which is connected to the lower electrode via the hole, on the second insulating film by patterning the aluminum film and the underlying conductive film.

15. A manufacturing method of a semiconductor device according to claim 14, wherein the underlying conductive film is formed of one of titanium nitride, titanium nitride/titanium laminated layer, and tungsten nitride.

16. A semiconductor device manufacturing method according to claim 14, wherein a minimum thickness of the underlying conductive film is formed thicker than 40 nm at the bottom of the hole when the platinum constituting the lower electrode is formed at a high temperature.

17. A semiconductor device manufacturing method according to claim 14, wherein the dielectric film is formed of ferroelectric material.

18. A semiconductor device manufacturing method according to claim 14, wherein upper portion of the hole is formed wider than lower portion.

19. A semiconductor device manufacturing method according to claim 14, wherein the aluminum film is made of material in which other elements are added to aluminum.

20. A semiconductor device manufacturing method according to claim 14, further comprising the step of:
forming a transistor, which is covered with the first insulating film, over the semiconductor substrate.
